(19) United States
(12) Patent Application Publication
(10) Pub. No.: US 2014/0167778 A1
(43) Pub. Date: Jun. 19, 2014

(54) BATTERY MANAGEMENT SYSTEM AND INTEGRATED BATTERY MANAGEMENT DEVICE

(71) Applicants: Akinobu Todani, Simoina-gun (JP); Shinta Nakano, Iida-shi (JP)

(72) Inventors: Akinobu Todani, Simoina-gun (JP); Shinta Nakano, Iida-shi (JP)

(73) Assignee: OMRON AUTOMOTIVE ELECTRONICS CO., LTD., Aichi (JP)

(21) Appl. No.: 14/109,580

(22) Filed: Dec. 17, 2013

(30) Foreign Application Priority Data
Dec. 19, 2012 (JP) 2012-276684

(51) Int. Cl. G01R 31/36

(52) U.S. Cl. CPC G01R 31/3606
USPC 324/434

(57) ABSTRACT

A battery management system has battery cell management devices that correspond to battery modules in which a plurality of battery cells are connected in series, and a battery pack management device that corresponds to a battery pack in which the battery modules are connected in series. Each of the battery cell management devices detects a voltage of each of the battery cells via a first detection line connected to both electrodes of each of the battery cells, and transmits data indicating the voltage to the battery pack management device via a communication line.

### BACKGROUND OF THE INVENTION

1. Technical Field

The present invention relates to a system for managing a battery pack in which a plurality of battery cells are connected in series.

2. Related Art

FIGS. 5 and 6 are diagrams illustrating conventional battery management systems 200 and 200′. The battery management systems 200 and 200′ are mounted in electric vehicles, such as an electric car and an electric motorcycle. A motor 60 is a drive source of an electric vehicle. A battery pack K is a power supply for the motor 60. A plurality of battery cells C are connected in series to constitute battery modules M1 to Mn. A plurality of the battery modules M1 to Mn are connected in series to constitute a battery pack K.

Cell Monitoring Units (CMUs) 21 to 2n are provided to correspond to the battery modules M1 to Mn, respectively. The cell monitoring units 21 to 2n are accommodated in separate cases 41 to 4n, respectively. A cell voltage monitoring unit 2b, connectors 2d, 2i, 2j and 2o, and internal wiring lines (patterns) Lb, T1a to Tna, F11 to Fni, and F1o to Fno are mounted on each of the substrates 31 to 3n of the cell monitoring units 21 to 2n.

An end of each external wiring line, for example, electric wire or harness, La is connected to both electrodes, a positive electrode and a negative electrode, of a battery cell C in each of the battery modules M1 to Mn. The other end of each external wiring line La is connected to one end of a corresponding internal wiring line Lb among multiple internal wiring lines Lb on each of the substrates 31 to 3n of the cell monitoring units 21 to 2n via the connectors 2d. The other end of each internal wiring line Lb is connected to the cell voltage monitoring unit 2b.

The cell voltage monitoring unit 2b detects a voltage of the corresponding battery cell C via the internal wiring line Lb, the connector 2d, and the external wiring line La. The external wiring line La and the internal wiring line Lb are detection lines for detecting a voltage of each battery cell C.

A battery management unit (BMU) 11 (or 11′) is in one-to-one correspondence with the battery pack K. The battery management unit 11 (or 11′) is accommodated in a case 40 (or 40′) which is separate from those in which the cell monitoring units 21 to 2n are accommodated. A control unit 1a, a battery pack voltage monitoring unit 1b, a communication unit 1d, connectors 1g, 1h, 1i, 1j, and 1o, and internal wiring lines Ld, Lf, Pa, Pb, Fo, Fi, and Ta are mounted on the substrate 30 (or 30′) of the battery management unit 11 (or 11′).

An end of an external wiring line Lc is connected to a positive electrode of the battery cell Cn disposed at the highest potential side of the battery pack K. The other end of the external wiring line Lc is connected to an end of an internal wiring line Ld on the substrate 30 (or 30′) of the battery management unit 11 (or 11′) via the connector 1g. The other end of the internal wiring line Ld is connected to the battery pack voltage monitoring unit 1b.

An end of an external wiring line Le is connected to a negative electrode of the battery cell C1 disposed at the lowest potential side of the battery pack K. The other end of the external wiring line Le is connected to an end of the internal wiring line Lf on the substrate 30 (or 30′) of the battery management unit 11 (or 11′) via the connector 1h. The other end of the internal wiring line Lf is connected to the battery pack voltage monitoring unit 1b.

The battery pack voltage monitoring unit 1b detects a voltage of the battery pack K via the internal wiring lines Ld and Lf, the connectors 1g and 1h, and the external wiring lines Lc and Le. The wiring lines Lc, Ld, Le, and Lf are detection lines for detecting a voltage of the battery pack K.

The communication unit 1d and each of the cell voltage monitoring units 2b of the cell monitoring units 21 to 2n are connected in series to each other via the external wiring lines F, F1 to Fn, the internal wiring lines Fo, Fi, F1o to Fno, F1i to Fni, and the connectors 1o, 1i, 2i, and 2o. The wiring lines F, F1 to Fn, Fo, Fi, F1o to Fno, and F1i to Fni are numbering lines used when the battery management unit 11 (or 11′) allocates identification numbers to the cell monitoring units 21 to 2n, respectively.

In FIG. 5, the communication unit 1d of the battery management unit 11 is connected in series to each of the cell voltage monitoring units 2b disposed between the cell voltage monitoring unit 2b of the cell monitoring unit 21 at the lowest potential side of the battery pack K and the cell voltage monitoring unit 2b of the cell monitoring unit 2n at the highest potential side of the battery pack K, via the numbering lines F1, F, Fo, Fi, F1i, Fno and the connectors 1o, 1i, 2i, and 2o.

In FIG. 6, the communication unit 1d of the battery management unit 11′ is connected in series to each of the cell voltage monitoring units 2b disposed between the cell voltage monitoring unit 2b of the cell monitoring unit 2n at the highest potential side of the battery pack K and the cell voltage monitoring unit 2b of the cell monitoring unit 21 at the lowest potential side of the battery pack K, via the numbering lines Fn, F, Fo, Fi, Fni, F1o and the connectors 1o, 1i, 2i, and 2o.

The communication unit 1d and each of the cell voltage monitoring units 2b of the cell monitoring units 21 to 2n are connected in parallel to each other via the external wiring lines T and T1 to Tn, the internal wiring lines Ta, T1a to Tna, and the connectors 1j and 2j. The wiring lines T, T1 to Tn, Ta, and T1a to Tna are communication lines for performing CAN (Controller Area Network) communication between the battery management unit 11 (or 11′) and each of the cell monitoring units 21 to 2n.

The control unit 1a of the battery management unit 11 (or 11′) is connected to the battery pack voltage monitoring unit 1b via the internal wiring line Pa, and to the communication unit 1d via the internal wiring line Pb. The control unit 1a allocates identification numbers to the cell monitoring units 21 to 2n via the communication unit 1d, the numbering lines F, F1 to Fn, Fo, Fi, F1o to Fno, and F1i to Fni, and the communication lines T, T1 to Tn, Ta, T1a to Tna, etc. The cell voltage monitoring units 2b of the cell monitoring units 21 to 2n store their own identification numbers allocated by the battery management unit 11 (or 11′).

Each of the cell voltage monitoring units 2b of the cell monitoring units 21 to 2n transmits data indicating the detected voltage of each battery cell to the battery management unit 11 (or 11′) via the communication lines T, T1 to Tn, Ta, T1a to Tna, etc. The control unit 1a of the battery management unit 11 (or 11′) receives the data indicating the voltage of each battery cell C from each of the cell monitoring units 21 to 2n via the communication unit 1d and the communication lines T, T1 to Tn, Ta, T1a to Tna, etc. The control unit 1a also determines if there are abnormalities, based on the data and the voltage of the battery pack K detected by the battery pack voltage monitoring unit 1b.

The construction of the battery management system 200 (or 200′) is disclosed in Japanese Patent Publication Laying-Open Nos. 11-252809, 2009-89521, 2010-279120, 2011-72161, 2011-107009, and 2012-105533. Japanese Patent Publication Laid-open No. 11-252809 discloses a technology in which whether there are abnormalities is determined based on the voltage of a battery cell or a battery pack. Japanese Patent Publication Laid-open No. 2009-89521 discloses a numbering method for cell monitoring units. Japanese Patent Publication Laid-open No. 2010-279120 discloses a technology in which a voltage matching unit is provided between a control unit and a communication unit so that a communication line can be shared.

Japanese Patent Publication Laid-open Nos. 2011-72161, 2011-107009, and 2012-105533 disclose measures for addressing an increase in the number of battery modules. In Japanese Patent Publication Laid-open No. 2011-72161, a representative voltage value among voltage values of battery cells is transmitted to a control unit from a battery module monitoring circuit in order to reduce a data transmission time. In Japanese Patent Publication Laid-open No. 2011-107009, each of the monitoring circuits corresponding to battery cells, and a control unit are connected in parallel to each other, and the output of the monitoring circuits other than the monitoring circuits which output a digital signal is set to a high impedance state. In Japanese Patent Publication Laid-open No. 2012-105533, a switch array is provided between two controllers and a battery pack, the conductive state of the switch array is controlled by one of the two controllers, and the voltage of each battery module is detected by the other controller.

As described above, the cell monitoring units are provided to correspond to the battery modules of the battery pack. Therefore, the number of the cell monitoring units correspondingly increases as the number of the battery modules increases. This also leads to an increase in the number of external wiring lines which are connected between the cell monitoring units or between the cell monitoring unit and the battery management unit. Furthermore, the space occupied by the battery management system in an electric vehicle increases as the number of cell monitoring units and/or the number of external wiring lines increase. For example, in an electric vehicle with a compact body like an electric motorcycle, if the space occupied by the battery management system is large, such a battery management system is difficult to be mounted. This may force the number of battery modules and that of cell monitoring units to be reduced.

### SUMMARY

One or more embodiments of the invention reduces the space occupied by a battery management system.

According to one or more embodiments of the invention, a battery management system includes battery cell management devices provided to correspond to battery modules in each of which battery cells are connected in series, and battery pack management devices provided to correspond to battery packs in each of which the battery modules are connected in series. The battery cell management device may detect a voltage of each battery cell via a first detection line connected to both electrodes of each battery cell, and transmit data indicating the voltage to the battery pack management device via a communication line. The battery pack management device may detect a voltage of the battery pack via a second detection line connected to both electrodes, a highest potential side electrode and a lowest potential side electrode, of the battery pack, and determine if there are abnormalities based on the voltage and the data indicating the voltage of each battery cell which is received via the communication line from each battery cell management device. At least one of the battery cell management devices and the battery pack management device are mounted on the same substrate to constitute an integrated battery management device.

With this construction, the number of devices used is reduced as compared with conventional technology because the battery cell management devices and the battery pack management device are mounted on the same substrate to constitute the integrated battery management device and because the integrated battery management device is accommodated in a casing. Furthermore, the number of external wiring lines can be reduced because internal wiring lines are provided on the same substrate in order to connect the battery cell management devices and the battery pack management device instead of external wiring lines which have been conventionally used to connect battery cell management devices and a battery pack management device. Accordingly, one or more embodiments of the invention can reduce the space occupied by the battery management system as compared with a conventional case where the battery cell management device and the battery pack management device are mounted in separate substrates.

Furthermore, the communication line which connects the battery cell management device and the battery pack management device which constitute the integrated battery management device may be provided as an internal wiring line on the same substrate.

The integrated battery management device may be constituted by mounting the battery cell management device at a lowest potential side of the battery pack which corresponds to the battery module disposed at a lowest potential side of the battery pack, and the battery pack management device on the same substrate, and providing a lowest potential-side second detection line used for the battery pack management device to detect a voltage of the battery pack and a first detection line used for detecting a voltage of the battery cell at the lowest potential side of the battery pack on the same substrate as internal wiring lines in a manner that the first detection line and the lowest potential-side second detection line are connected. In this case, other battery cell management devices and the battery pack management device which are not mounted on the same substrate are connected via a communication line including an external wiring line.

The integrated battery management device may be constituted by mounting the battery cell management device at a highest potential side of the battery pack which corresponds to the battery module disposed at the highest potential side of the battery pack, and the battery pack management device on the same substrate, and providing a highest potential-side second detection line used for the battery pack management device to detect a voltage of the battery pack and a first detection line used for detecting a voltage of the battery cell at the highest potential side of the battery pack on the same substrate as internal wirings in a manner that the highest potential-side second detection line and the first detection line are connected. In this case, the battery cell management devices which are not mounted on the same substrate and the battery pack management device are connected via a communication line including an external wiring line.

Furthermore, the battery pack management device may determine if there are abnormalities based on a result of comparison between a voltage value of the battery pack and a total value of the voltages of respective battery cells.

According to one or more embodiments of the present invention, it is possible to reduce a space occupied by a battery management system.

### BRIEF DESCRIPTION OF THE DRAWINGS

FIG. 1 is a diagram illustrating a battery management system according to a first embodiment of the present invention;

FIG. 2 is a diagram illustrating a battery management system according to a second embodiment of the present invention;

FIG. 3 is a flowchart illustrating operation of cell monitoring units of FIGS. 1 and 2;

FIG. 4 is a flowchart illustrating operation of battery management devices of FIGS. 1 and 2;

FIG. 5 is a diagram illustrating a conventional battery management system; and

FIG. 6 is a diagram illustrating another conventional battery management system.

### DETAILED DESCRIPTION

Hereinafter, embodiments of the present invention will be described with reference to the drawings. Identical or equivalent portions through all the drawings are represented by the same reference signs. In embodiments of the invention, numerous specific details are set forth in order to provide a more thorough understanding of the invention. However, it will be apparent to one of ordinary skill in the art that the invention may be practiced without these specific details. In other instances, well-known features have not been described in detail to avoid obscuring the invention.

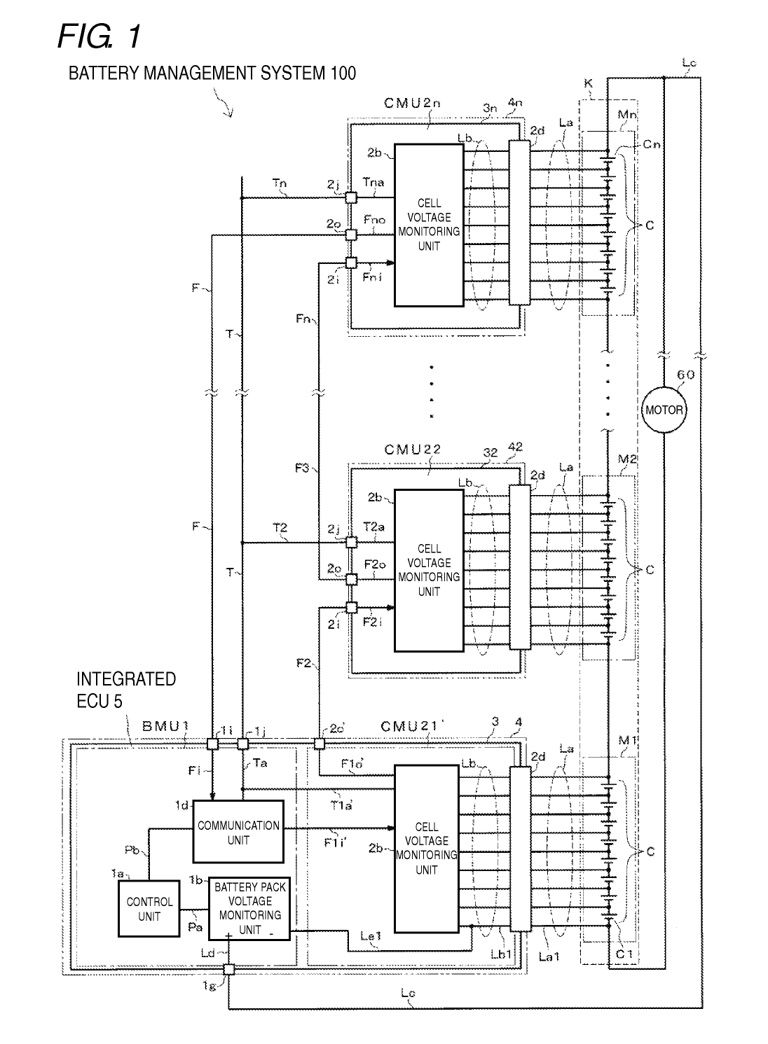

First, the construction of a battery management system 100 according to a first embodiment is described with reference to FIG. 1.

The battery management system 100 is mounted in electric vehicles such as an electric car and an electric motorcycle. A motor 60 is a drive source of an electric vehicle. A battery pack K is a power supply for the motor 60. A plurality of battery cells C are connected in series to constitute battery modules M1 to Mn. A plurality of the battery modules M1 to Mn are connected in series to constitute a battery pack K.

Cell Monitoring Units (CMUs) 21′ and 22 to 2n are provided to correspond to the battery modules M1 to Mn, respectively. The cell monitoring units 21′ and 22 to 2n are examples of a “battery cell management device” of one or more embodiments of the present invention.

The cell monitoring units 22 to 2n among all of the cell monitoring units are accommodated in separate cases 42 to 4n, respectively. Cell voltage monitoring units 2b, connectors 2d, 2i, 2j and 2o, and internal wiring lines (patterns) Lb, T2a to Tna, F2i to Fni, and F2o to Fno are mounted on substrates 32 to 3n of the cell monitoring units 22 to 2n.

An integrated ECU (Electronic Control Unit) 5 is constituted by mounting the cell monitoring unit 21′ corresponding to the battery module M1 disposed at the lowest potential side of the battery pack K, and a BMU (Battery Management Unit) 1 on the same substrate 3. The battery management unit 1 is in one-to-one correspondence with the battery pack K. The integrated ECU 5 is accommodated in a case 4 which is separate from those in which the cell monitoring units 22 to 2n are accommodated. The battery management unit 1 is an example of a “battery pack management device” of one or more embodiments of the present invention. The integrated ECU 5 is an example of an “integrated battery management device” of one or more embodiments of the present invention.

The cell voltage monitoring unit 2b, connectors 2d and 2o′, internal wiring lines Lb and F1o′, part of internal wiring lines T1a′, F1i′, and Le1 are mounted within a portion on the substrate 3 where the cell monitoring unit 21′ is to be formed.

A control unit 1a, a battery pack voltage monitoring unit 1b, a communication unit 1d, connectors 1g, 1i, and 1j, internal wiring lines Ld, Pa, and Pb, Fi, and Ta, and part of internal wiring lines T1a′, F1i′, and Le1 are mounted within a portion on the substrate 3 where the battery management unit 1 is to be formed.

An end of each external wiring line, for example, electric wire or harness, La is connected to both electrodes, a positive electrode and a negative electrode, of a battery cell C in each of the battery modules M1 to Mn. The other end of each external wiring lines La is connected to an end of a corresponding internal wiring line Lb among the internal wiring lines Lb formed on each of the substrates 3, 32 to 3n of the cell monitoring units 21′, 22 to 2n via the connectors 2d. The other end of each internal wiring line Lb is connected to the cell voltage monitoring unit 2b.

The cell voltage monitoring unit 2b detects a voltage of the corresponding battery cell C via the internal wiring line Lb, the connector 2d, and the external wiring line La. The wiring lines La and Lb are examples of a “first detection line” of one or more embodiments of the present invention.

An end of an external wiring line Lc is connected to a positive electrode of the battery cell Cn disposed at the highest potential side of the battery pack K. The other end of the external wiring line Lc is connected to an end of an internal wiring line Ld on the substrate 3 via the connector 1g. The other end of the internal wiring line Ld is connected to the battery pack voltage monitoring unit 1b.

An end of an internal wiring Le1 provided on the substrate 3 is connected to the battery pack voltage monitoring unit 1b. The other end of the internal wiring Le1 is connected to a negative electrode-side external wiring line La1 for detecting a voltage of the battery cell C1 at the lowest potential side of the battery pack K via the wiring line Lb1 which is disposed at the lowest potential side among the wiring lines Lb, and the connector 2d.

The battery pack voltage monitoring unit 1b detects a voltage of the battery pack K via the internal wiring lines Ld, Le1, and Lb1, the connectors 1g and 2d, and the external wiring lines Lc and La1. The wiring lines Ld, Lc, Le1, Lb1, and La1 are examples of “second detection lines” of one or more embodiments of the present invention. Among these, the wiring line Le1 is an example of a “lowest potential-side second detection line” of one or more embodiments of the present invention.

The communication unit 1d of the battery management unit 1, and the cell voltage monitoring units 2b of the respective cell monitoring units 21′, and 22 to 2n are connected in series via the internal wiring lines F1i′, F1o′, F2o to Fno, Fi, and F2i to Fni, the external wiring lines F, and F2 to Fn, and the connectors 2o′, 1i, 2i, and 2o.

Specifically, the communication unit 1d and the cell voltage monitoring unit 2b of the cell monitoring unit 21′ are connected via the internal wiring F1i′ on the substrate 3. The cell voltage monitoring units 2b of the cell monitoring units 21′ and 22 are connected to each other via the internal wiring line F1o′ on the substrate 3, the connector 2o′, the external wiring line F2, the connector 2i on the substrate 32 and the internal wiring line F2i. The cell voltage monitoring units 2b of the adjoining cell monitoring units 22 to 2n are connected to each other via the internal wiring lines F2o to Fn-1o and F3i to Fni on the substrates 32 to 3n, the connectors 2i and 2o, and the external wiring lines F3 to Fn (here, wiring lines other than the wiring lines F2o, Fni, F3, and Fn are not illustrated).

Furthermore, the cell voltage monitoring unit 2b of the cell monitoring unit 2n and the communication unit 1d of the battery management unit 1 are connected to each other via the internal wiring line Fno on the substrate 3n, the connector 2o, the external wiring line F, the connector 1i on the substrate 3, and the internal wiring line Fi. The wiring lines F1i′, F1o′, F2o to Fno, Fi, F2i to Fni, F, and F2 to Fn are numbering lines used when the battery management unit 1 allocates identification numbers to the cell monitoring units 21′. and 22 to 2n.

The communication unit 1d and each of the cell voltage monitoring units 2b of the respective cell monitoring units 21′, and 22 to 2n are connected in parallel via the external wiring lines T, and T2 to Tn, and the internal wiring lines Ta, T1a′ to Tna, and the connectors 1j and 2j. The wiring lines T, T2 to Tn, Ta, T1a′, and T2a to Tna are wiring lines for performing CAN (Controller Area Network) communication between the battery management unit 1 and each of the cell monitoring units 21′ and 22 to 2n.

The control unit 1a of the battery management unit 1 is connected to the battery pack voltage monitoring unit 1b via the internal wiring line Pa, and to the communication unit 1d via the internal wiring line Pb. The control unit la allocates identification numbers to the respective cell monitoring units 21′ and 22 to 2n via the communication unit 1d, the numbering lines F1i′, F1o′, F2o to Fno, F1, F2i to Fni, F, and F2 to Fn, communication lines T, T2 to Tn, T1a′, T2a to Tna, and Ta. The respective cell voltage monitoring units 2b of the cell monitoring units 21′ and 22 to 2n store their own identification numbers allocated by the battery management unit 1 in an internal memory.

Each of the cell voltage monitoring units 2b of the cell monitoring units 21′ and 22 to 2n transmits voltage data indicating a detected voltage of each battery cell C to the battery management unit 1 via the communication lines T, T2 to Tn, T1a′, T2a to Tna, and Ta. The control unit 1a of the battery management unit 1 receives the voltage data of each battery cell C from each of the cell monitoring units 21′ and 22 to 2n via the communication unit 1d and the communication lines T, T2 to Tn, T1a′, T2a to Tna, and Ta. The control unit 1a determines if there are abnormalities, based on the voltage data and the voltage of the battery pack K detected by the battery pack voltage monitoring unit 1b.

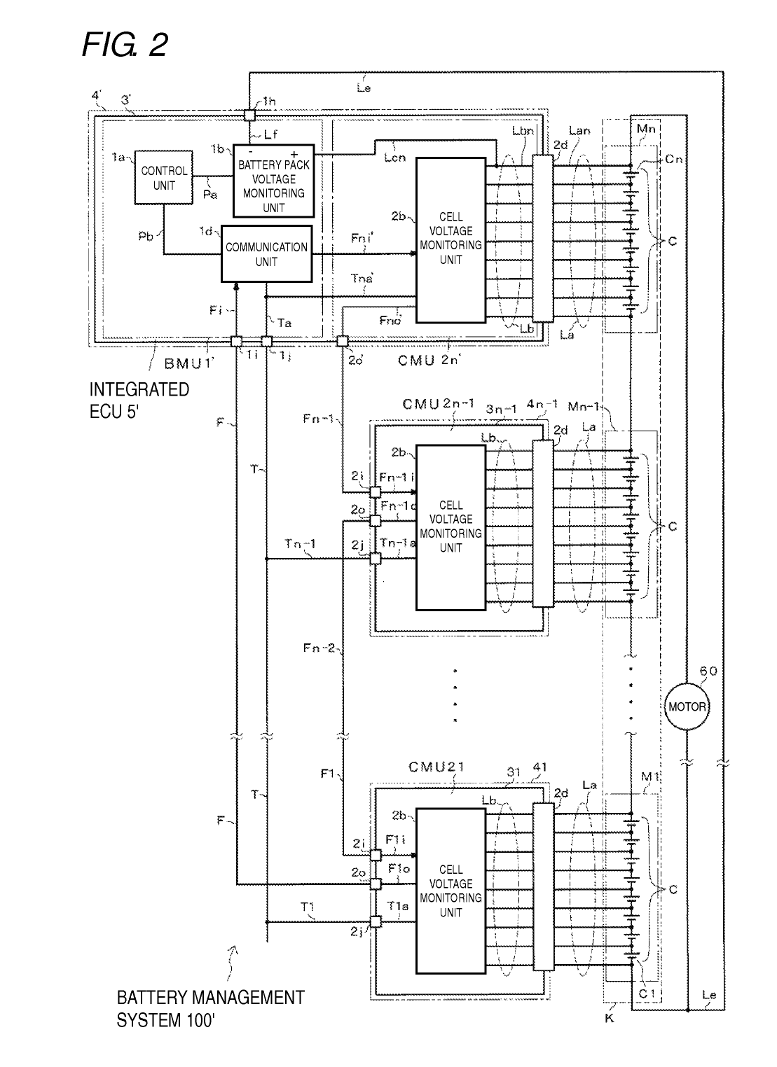

Next, the construction of a battery management system 100′ according to a second embodiment is described with reference to FIG. 2. A description about portions substantially the same as those of the battery management system 100 of FIG. 1 will be omitted.

The battery management system’ 100 is mounted in an electric vehicle. Cell Monitoring Units (CMUs) 21 to 2n-1, and 2n′ are provided to be in one-to-one correspondence with battery modules M1 to Mn, respectively. The cell monitoring units 21 to 2n-1 and 2n′ are examples of a “battery cell management device” of one or more embodiments of the present invention.

The cell monitoring units 21 to 2n-1 among all of the cell monitoring units are accommodated in separate cases 41 to 4n-1, respectively. Cell voltage monitoring units 2b, connectors 2d, 2i, 2j and 2o, and internal wiring lines Lb, T1a to Tn-1a, F1i to Fn-1i, and F1o to Fn-1o are mounted on substrates 31 to 3n-1 of the cell monitoring units 21 to 2n-1.

An integrated ECU 5′ is constituted by mounting the cell monitoring unit 2n′ corresponding to the battery module Mn disposed at the highest potential side of the battery pack K, and a battery management unit 1′ on the same substrate 3′. The battery management unit 1′ is provided to be in one-to-one correspondence with the battery pack K. The integrated ECU 5′ is accommodated in a case 4′ which is separate from those in which the cell monitoring units 21 to 2n-1 are accommodated. The battery management unit 1′ is an example of a “battery pack management device” of one or more embodiments of the present invention. The integrated ECU 5′ is an example of an “integrated battery management device” of one or more embodiments of the present invention.

The cell voltage monitoring unit 2b, connectors 2d and 2o′, internal wiring lines Lb and Fno′, part of internal wiring lines Tna′, Fni′, and Lcn are mounted within a portion on the substrate 3 where the cell monitoring unit 2n′ is to be formed.

A control unit 1a, a battery pack voltage monitoring unit 1b, a communication unit 1d, connectors 1h, 1i, and 1j, internal wiring lines Lf, Pa, and Pb, Fi, and Ta, and part of internal wiring lines Tna′, Fni′, and Lcn are mounted within a portion on the substrate 3 where the battery management unit 1′ is to be formed.

Cell voltage monitoring unit 2b of the respective cell monitoring unit 21 to 2n-1 and 2n′ detect the voltage of each battery cell C in each of the battery modules M1 to Mn via the wiring lines Lb and La and the connectors 2d. The wiring lines La and Lb are examples of a “first detection line” of one or more embodiments of the present invention.

An end of an external wiring line Le is connected to a negative electrode of the battery cell C1 disposed at the lowest potential side of the battery pack K. The other end of the external wiring line Le is connected to an end of the internal wiring line Lf on the substrate 3 of the battery management unit 1 via the connector 1h. The other end of the internal wiring line Lf is connected to the battery pack voltage monitoring unit 1b.

An end of the internal wiring line Lcn provided on the substrate 3′ is connected to the battery pack voltage monitoring unit 1b. The other end of the internal wiring line Lcn is connected to the wiring line Lbn disposed at the highest potential side of the battery pack K among the internal wiring lines Lb via the connector 2d, and to the external wiring line Lan for the positive electrode which detects a voltage of the battery cell Cn disposed at the highest potential side of the battery pack K

The battery pack voltage monitoring unit 1b detects a voltage of the battery pack K via the internal wiring lines Lf, Lcn, and Lbn, the connectors 1h and 2d, and the external wiring lines Le and Lan. The wiring lines Lf, Lcn, Lbn, Le, and Lan are examples of “second detection lines” of one or more embodiments of the present invention. Among these, the wiring line Lcn is an example of a “highest potential-side second detection line” of one or more embodiments of the present invention.

The communication unit 1d of the battery management unit 1, and the cell voltage monitoring units 2b of the respective cell monitoring units 21 to 2n-1 and 2n′ are connected in series via the internal wiring lines Fni′, Fno′, Fn-1o to F1o, Fi, and Fn-1i to F1i, the external wiring lines F, and Fn-1 to F1, and the connectors 2o′, 1i, 2o, and 2i.

Specifically, the communication unit 1d and the cell voltage monitoring unit 2b of the cell monitoring unit 2n′ are connected to each other via the internal wiring Fni′ on the substrate 3′. Further, the cell voltage monitoring units 2b of the cell monitoring units 2′ and 2n-1 are connected to each other via the internal wiring line Fno′ on the substrate 3′, the connector 2o′, the external wiring line Fn-1, the connector 2i on the substrate 3n-1, and the internal wiring line Fn-1i. The cell voltage monitoring units 2b of the adjoining cell monitoring units 2n-1 to 21 are connected in series via the internal wiring lines Fn-1o to F2o and Fn-2i to F1i, the connectors 2i and 2o, and the external wiring lines Fn-2 to F1 on the substrates 3n-1 to 31 (here, wiring lines other than the wiring lines Fn-1o, F1i, Fn-2, and F1 are not illustrated).

Furthermore, the cell voltage monitoring unit 2b of the cell monitoring unit 21 and the communication unit 1d of the battery management unit 1′ are connected to each other via the internal wiring line F1o, the connector 2o, and the external wiring line F on the substrate 31, and the connector 11 and the internal wiring line Fi on the substrate 3′. The wiring lines Fni′, Fno′, Fn-1o to F1o, Fi, Fn-1i to F1i, F, and Fn-1 to F1 are numbering lines used when the battery management unit 1′ allocates identification numbers to the cell monitoring units 21 to 2n-1 and 2n′.

The communication unit 1d and the cell voltage monitoring units 2b of the respective cell monitoring units 21 to 2n-1 and 2n′ are connected in parallel via the external wiring lines T, and Tn-1 to T1, the internal wiring lines Ta, Tna′, and Tn-1a to T1a, and the connectors 1j and 2j. The wiring lines T, Tn-1 to T1, Ta, Tna′, and Tn-1a to T1a are wiring lines for performing CAN (Controller Area Network) communication between the battery management unit 1′ and each of the cell monitoring units 21 to 2n-1 and 2n′, and examples of a “communication line” of one or more embodiments of the present invention.

The control unit 1a of the battery management unit 1′ is connected to the battery pack voltage monitoring unit 1b via the internal wiring line Pa, and to the communication unit 1d via the internal wiring line Pb. The control unit 1a allocates identification numbers to the respective cell monitoring units 21 to 2n-1 and 2n′ via the communication unit 1d, the numbering lines Fni′, Fno′, Fn-1o to F1o, Fi, Fn-1i to F1i, F, and Fn-1 to F1 and the communication lines T, Tn-1 to T1, Ta, Tna′ and Tn-1a to T1a. The respective cell voltage monitoring units 2b of the cell monitoring units 21 to 2n-1 and 2n′ store their own identification numbers allocated by the battery management unit 1′ in an internal memory.

Each of the cell voltage monitoring units 2b of the cell monitoring units 21 to 2n-1 and 2n′ transmits voltage data indicating a detected voltage of each battery cell C to the battery management unit 1′ via the communication lines T, Tn-1 to T1, Ta, Tna′, and Tn-1a to T1a. The control unit 1a of the battery management unit 1′ receives the voltage data of each battery cell C from each of the cell monitoring units 21 to 2n-1 and 2n′ via the communication unit 1d and the communication lines T, Tn-1 to T1, Ta, Tna′, and Tn-1a to T1a. The control unit 1a determines if there are abnormalities, based on the voltage data and the voltage of the battery pack K detected by the battery pack voltage monitoring unit 1b. Details of the determination will be described below.

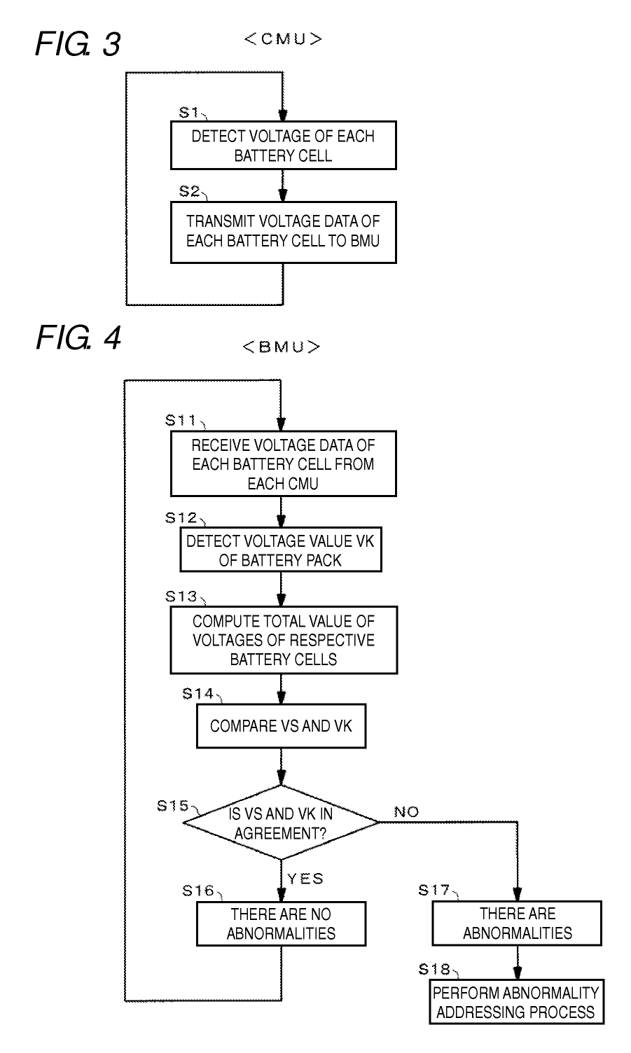

Next, operation of the cell monitoring units 21′, 22 to 2n, 21 to 2n-1, and 2n′ and the battery management units 1 and 1′ of FIGS. 1 and 2 is described with reference to FIGS. 3 and 4. Each step in FIG. 3 is performed by the cell voltage monitoring units 2b of the cell monitoring unit 21′, 22 to 2n, 21 to 2n-1, and 2n′. Each step in FIG. 4 is performed by the control units 1a of the battery management units 1 and 1′.

The cell voltage monitoring units 2b of the respective cell monitoring units 21′, 22 to 2n, 21 to 2n-1, and 2n′ detect the voltage of each battery cell C in the corresponding battery modules M1 to Mn via the detection lines Lb and La with a predetermined period (Step S1 of FIG. 3). And the voltage data indicating voltage values of the respective battery cells C is transmitted to the battery management unit 1 (or 1′) via the communication line (here, reference signs are omitted) (Step S2).

The control unit 1a of the battery management unit 1 (or 1′) receives the voltage data of each battery cell C from the cell voltage monitoring units 2b of the respective cell monitoring units 21′, 22 to 2n, 21 to 2n-1, and 2n′ via the communication units 1d and the communication lines (here, reference signs are omitted) with a predetermined period (Step S11 of FIG. 4). Subsequently, the battery pack voltage monitoring unit 1b detects a voltage Vk of the battery pack K via the detection line (here, reference signals are omitted) with a predetermined period (Step S12).

Next, based on the voltage data of each battery cell C, the control unit 1a computes a total value Vs of the voltages of the respective battery cells C (Step S13), and compares the total value Vs and the voltage value Vk of the battery pack K (Step S14). Next, it is determined if the total value Vs of the voltages of the respective battery cells C and the voltage value Vk of the battery pack K are in agreement (Step S15).

Here, when the total value Vs of the voltages of the respective battery cells C and the voltage value Vk of the battery pack K are in agreement here (YES in Step S15), the control unit 1a determines that there are no abnormalities (Step S16), and repeatedly performs Step S11 and the following steps.

On the other hand, when the total value Vs of the voltages of the respective battery cells C and the voltage value Vk of the battery pack K are not in agreement (NO in Step S15), the control unit 1a determines that there are abnormalities (Step S17), and performs an abnormality addressing process (Step S18). The abnormalities of this case may include, for example, degradation of the battery cells, failure of the battery cell management device, and disconnection in the detection line and/or communication line. For this reason, as the abnormality addressing process of Step S18, control of stopping electricity supply to the motor 60 from the battery pack K after a stop of an electric vehicle is performed, for example.

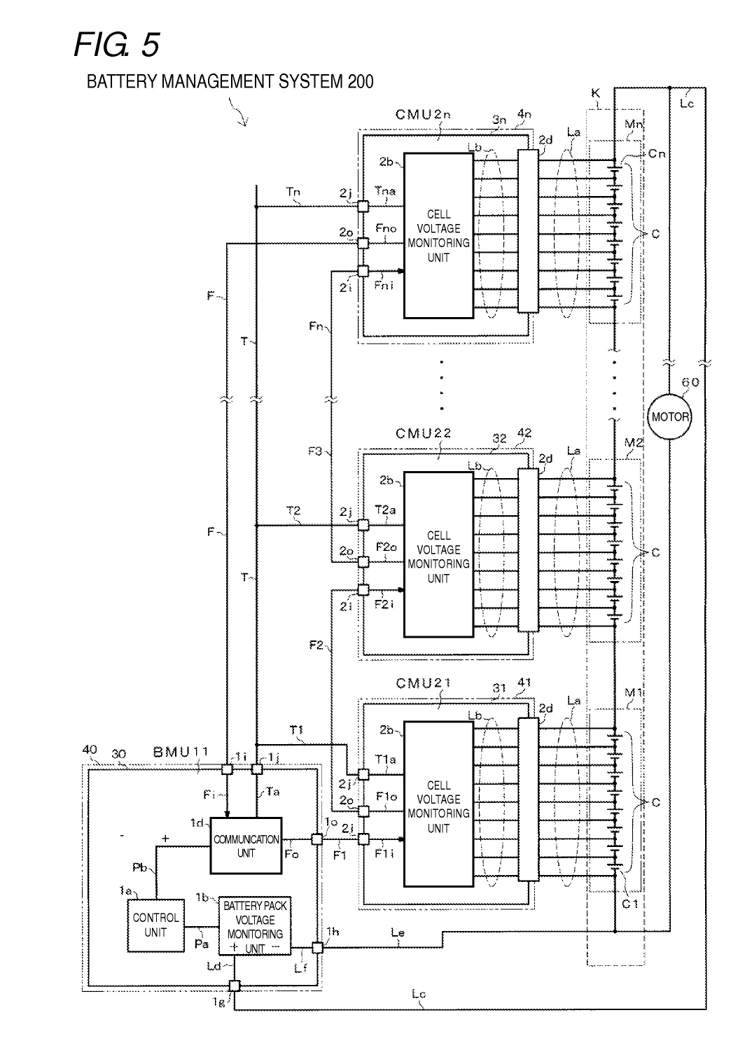

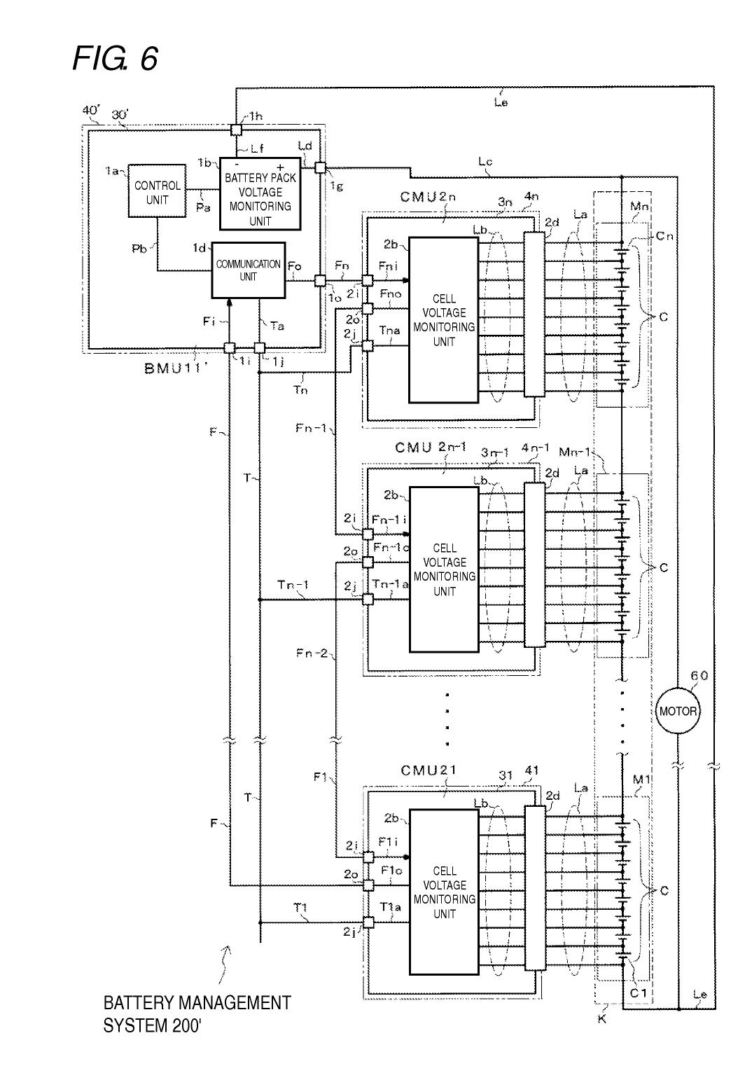

According to the above, the cell monitoring units 21′, 22 to 2n, 21 to 2n-1 and 2n′ and the battery management unit 1 (or 1′) are mounted on the same substrate 3 (or 3′) to constitute the integrated ECU 5 (or 5′). For this reason, the integrated ECU 5 (or 5′) can be accommodated in a case 4 (or 4′), thereby reducing the number of devices used as compared with the conventional arts of FIGS. 5 and 6.

In addition, in the conventional examples of FIGS. 5 and 6, in order to connect the cell monitoring unit 21 (or 2n) and the battery management unit 11 (or 11′), the external wiring lines F1, T1, Fn, and Tn are provided. Instead of this, according to the above, the internal wiring lines F11′, T1a′, Fni′, and Tna′ are provided on the same substrate 3 (or 3′) so that the battery management unit 1 (or 1′) and the cell monitoring unit 21′ (or 2n′) which constitute the integrated ECU 5 (or 5′) can be connected to each other. That is, the numbering line F1i′ (or Fni′) and the communication line T1a′ (or Tna′) between the cell monitoring unit 21′ (or 2n′) and the battery management unit 1 (or 1′) are provided on the same substrate 3 (or 3′) as the internal wiring lines. For this reason, the number of external wiring lines for the numbering lines and the communication lines can be reduced. Furthermore, since the connectors 10 of the battery management units 11 and 11′ and the connectors 2i and 2j of the cell monitoring units 21 and 2n of FIGS. 5 and 6 are omitted, the number of connectors can also be reduced.

In the conventional examples of FIG. 5 and FIG. 6, in order for the battery pack voltage monitoring units 1b of the battery management units 11 and 11′ to detect the voltage of the battery pack K, the external wiring lines Lc and Le are provided separately from the detection lines La for the battery cells C. Instead of this construction, according to the first embodiment of FIG. 1, the cell monitoring unit 21′ at the lowest potential side of the battery pack K, and the battery management unit 1 are mounted on the same substrate 3 to constitute the integrated ECU 5. In addition, in order for the battery pack voltage monitoring unit 1b of the battery management unit 1 to detect the voltage of the battery pack K, the detection line Le1 at the lowest potential side for detecting the voltage of the battery pack K and the detection line La1 for detecting the voltage of the battery cell C1 at the lowest potential side are provided on the same substrate 3 in a way that the detection line Le1 and the detection line La1 are connected.

In addition, according to the second embodiment of FIG. 2, the cell monitoring unit 2n′ at the highest potential side of the battery pack K, and the battery management unit 1′ are mounted on the same substrate 3′ to constitute the integrated ECU 5′. In addition, in order for the battery pack voltage monitoring unit 1b of the battery management unit 1′ to detect the voltage of the battery pack K, the detection line Lcn at the highest potential side for detecting the voltage of the battery pack K and the detection line Lan for detecting the voltage of the battery cell Cn at the highest potential side are provided on the same substrate 3′ in a way that the detection line Lcn and the detection line Lan are connected. For this reason, the number of external wiring lines for the detection lines can be reduced. Furthermore, as the connectors 1h and 1g of the battery management units 11 and 11′ of FIGS. 5 and 6 are omitted, the number of connectors can also be reduced.

Accordingly, one or more embodiments of the present invention can reduce the space occupied by the battery management system 100 (or 100′) in an electric vehicle as compared with a conventional case where the cell monitoring unit and the battery management unit are mounted on separate substrates.

The present invention can adopt a variety of embodiments besides the above. For example, although an example is set forth above in which the cell monitoring unit 21′ and 2n′ corresponding to the battery modules M1 and Mn disposed at the highest potential side or the lowest potential side of the battery pack K and the battery management units 1 and 1′ are integrated, the present invention is not limited to this. Aside from this example, any one of the cell monitoring units 22 to 2n-1 corresponding to the battery modules M2 to Mn-1 which are not disposed at the highest potential side and/or the lowest potential side of the battery pack K, and the battery management unit 1 (or 1′) may be mounted on the same substrate. In addition, any two or more cell monitoring units selected from among the cell monitoring units 21′, 22 to 2n, 21 to 2n-1, and 2n′ may be integrally mounted on the same substrate as the battery management unit 1 (or 1′).

Although an example is set forth above in which whether there are abnormalities are determined based on the total value Vs of the voltages of the respective battery cells C, and the voltage value Vk of the battery pack K, the present invention is not limited to this. Besides of this, whether there are abnormalities may be determined based on at least one from among a voltage value of each battery cell C, an operation value of the voltages of the respective battery cells C, a voltage value of the battery pack K, and an operation value of the voltage of the battery pack K, for example.

In addition, an example is set forth above in which one or more embodiments of the present invention is applied to the battery management systems 100 and 100′ and the integrated ECUs 5 and 5′ to be mounted in electric vehicles such as an electric car and/or an electric motor cycle, one or more embodiments of the present invention can also be applied to a battery management system and/or an integrated battery management unit to be mounted in a hybrid vehicle which is driven by electricity and other fuels, for example.

While the invention has been described with respect to a limited number of embodiments, those skilled in the art, having benefit of this disclosure, will appreciate that other embodiments can be devised which do not depart from the scope of the invention as disclosed herein. Accordingly, the scope of the invention should be limited only by the attached claims.

What is claimed is:

1. A battery management system comprising:
battery cell management devices that correspond to battery modules in which a plurality of battery cells are connected in series; and
a battery pack management device that corresponds to a battery pack in which the battery modules are connected in series,
wherein each of the battery cell management devices detects a voltage of each of the battery cells via a first detection line connected to both electrodes of each of the battery cells, and transmits data indicating the voltage to the battery pack management device via a communication line,
wherein the battery pack management device detects a voltage of the battery pack via a second detection line connected to both electrodes, a highest potential side electrode and a lowest potential side electrode, of the battery pack, and determines if there are abnormalities based on the voltage and data of a voltage of each of the battery cells which is received via the communication line from each of the battery cell management devices, and
wherein the battery pack management device and at least one of the battery cell management devices are mounted on a same substrate.

2. The battery management system according to claim 1,
wherein the communication line which connects the at least one of the battery cell management devices and the battery pack management device is provided on the same substrate as an internal wiring line.

3. The battery management system according to claim 1,
wherein one of the battery cell management devices at a lowest potential side of the battery pack which corresponds to the battery module disposed at the lowest potential side of the battery pack, and the battery pack management device, are mounted on the same substrate, and
wherein the lowest potential-side second detection line used for the battery pack management device to detect a voltage of the battery pack, and the first detection line for detecting a voltage of the battery cell disposed at the lowest potential side of the battery pack are provided on the same substrate as internal wiring lines in a manner that the first detection line and the lowest potential-side second detection line are connected to each other.

4. The battery management system according to claim 1,
wherein one of the battery cell management devices at a highest potential side corresponding to the battery module disposed at a highest potential side of the battery pack, and the battery pack management device, are mounted on the same substrate, and
wherein the highest potential-side second detection line used for the battery pack management device to detect a voltage of the battery pack, and the first detection line for detecting a voltage of the battery cell at the highest potential side of the battery pack are provided on the same substrate as internal wiring lines in a manner that the first detection line and the highest potential-side second detection line are connected to each other.

5. The battery management system according to claim 1,
wherein the battery pack management device determines if there are abnormalities based on a result of comparison between a voltage value of the battery pack and a total value of voltages of the respective battery cells.

6. An integrated battery management device comprising:
battery cell management devices that correspond to battery modules in which a plurality of battery cells are connected in series; and
a battery pack management device that corresponds to a battery pack in which the battery modules are connected in series,
wherein each of the battery cell management devices detects a voltage of each of the battery cells via a first detection line connected to both electrodes of each of the battery cells, and transmits data indicating the voltage to the battery pack management device via a communication line, and
wherein the battery pack management device detects a voltage of the battery pack via a second detection line connected to both electrodes, a highest potential side electrode and a lowest potential side electrode, of the battery pack, and determines if there are abnormalities based on the voltage and data of a voltage of each of the battery cells which is received via the communication line from each of the battery cell management devices, and
wherein the battery pack management device and the battery cell management devices are mounted on a same substrate.

7. The integrated battery management device according to claim 6,
wherein the communication line which connects the battery cell management device and the battery pack management device is provided on the same substrate as an internal wiring line.

8. The integrated battery management device according to claim 6,
wherein the integrated battery management device comprises one of the battery cell management devices at a lowest potential side corresponding to the battery module disposed at a lowest potential side of the battery pack, and the battery pack management device, mounted on the same substrate,
wherein the battery pack management device is connected to another of the battery cell management devices which is not mounted on the same substrate via the communication line including an external wiring line, and
wherein the lowest potential-side second detection line used for the battery pack management device to detect a voltage of the battery pack, and the first detection line for detecting a voltage of the battery cell at the lowest potential side of the battery pack are provided on the same substrate as internal wiring lines in a manner that the first detection line and the lowest potential-side second detection line are connected to each other.

9. The integrated battery management device according to claim 6,
wherein the integrated battery management device comprises one of the battery cell management devices at a highest potential side corresponding to the battery module disposed at a highest potential side of the battery pack, and the battery pack management device, mounted on the same substrate,
wherein the battery pack management device is connected to another of the battery cell management devices which is not mounted on the same substrate via the communication line including an external wiring line, and
wherein the highest potential-side second detection line used for the battery pack management device to detect a voltage of the battery pack, and the first detection line for detecting a voltage of the battery cell at the highest potential side of the battery pack are provided on the same substrate as internal wiring lines in a manner that the first detection line and the highest potential-side second detection line are connected to each other.

10. The integrated battery management device according to claim 6,
wherein the battery pack management device determines if there are abnormalities based on a result of comparison between a voltage value of the battery pack and a total value of voltages of the respective battery cells.

11. The battery management system according to claim 2,
wherein the battery cell management device at a lowest potential side of the battery pack which corresponds to the battery module disposed at the lowest potential side of the battery pack, and the battery pack management device are mounted on the same substrate, and
wherein the lowest potential-side second detection line used for the battery pack management device to detect a voltage of the battery pack, and the first detection line for detecting a voltage of the battery cell disposed at the lowest potential side of the battery pack are provided on the same substrate as internal wiring lines in a manner that the first detection line and the lowest potential-side second detection line are connected to each other.

12. The battery management system according to claim 2,
wherein the battery cell management device at a highest potential side corresponding to the battery module disposed at a highest potential side of the battery pack, and the battery pack management device are mounted on the same substrate, and
wherein the highest potential-side second detection line used for the battery pack management device to detect a voltage of the battery pack, and the first detection line for detecting a voltage of the battery cell at the highest potential side of the battery pack are provided on the same substrate as internal wiring lines in a manner that the first detection line and the highest potential-side second detection line are connected to each other.

13. The battery management system according to claim 2,
wherein the battery pack management device determines if there are abnormalities based on a result of comparison between a voltage value of the battery pack and a total value of voltages of the respective battery cells.

14. The battery management system according to claim 3,
wherein the battery pack management device determines if there are abnormalities based on a result of comparison between a voltage value of the battery pack and a total value of voltages of the respective battery cells.

15. The battery management system according to claim 4,
wherein the battery pack management device determines if there are abnormalities based on a result of comparison between a voltage value of the battery pack and a total value of voltages of the respective battery cells.

16. The battery management system according to claim 11,
wherein the battery pack management device determines if there are abnormalities based on a result of comparison between a voltage value of the battery pack and a total value of voltages of the respective battery cells.

17. The battery management system according to claim 12,
wherein the battery pack management device determines if there are abnormalities based on a result of comparison between a voltage value of the battery pack and a total value of voltages of the respective battery cells.

18. The integrated battery management device according to claim 7,
wherein the integrated battery management device comprises one of the battery cell management devices at a lowest potential side corresponding to the battery module disposed at a lowest potential side of the battery pack, and the battery pack management device, mounted on the same substrate,
wherein the battery pack management device is connected to another of the battery cell management devices which is not mounted on the same substrate via the communication line including an external wiring line, and
wherein the lowest potential-side second detection line used for the battery pack management device to detect a voltage of the battery pack, and the first detection line for detecting a voltage of the battery cell at the lowest potential side of the battery pack are provided on the same substrate as internal wiring lines in a manner that the first detection line and the lowest potential-side second detection line are connected to each other.

19. The integrated battery management device according to claim 7,
wherein the integrated battery management device comprises one of the battery cell management devices at a highest potential side corresponding to the battery module disposed at a highest potential side of the battery pack, and the battery pack management device, mounted on the same substrate,
wherein the battery pack management device is connected to another of the battery cell management devices which is not mounted on the same substrate via the communication line including an external wiring line, and
wherein the highest potential-side second detection line used for the battery pack management device to detect a voltage of the battery pack, and the first detection line for detecting a voltage of the battery cell at the highest potential side of the battery pack are provided on the same substrate as internal wiring lines in a manner that the first detection line and the highest potential-side second detection line are connected to each other.
